(19) United States
(12) Patent Application Publication
(10) Pub. No.: US 2009/0014910 A1
(43) Pub. Date: Jan. 15, 2009

(54) METHOD AND ARRANGEMENT FOR FORMING ELECTRONIC DEVICE

(75) Inventors: Esa Muukkonen, Vantaa (FI); Tero Peltola, Tampere (FI)

Correspondence Address: YOUNG & THOMPSON, 209 Madison Street, Suite 500, ALEXANDRIA, VA, 22314, US

(73) Assignee: PERLOS OYJ, Vantaa (FI)

(21) Appl. No.: 12/280,795

(22) PCT Filed: Feb. 22, 2007
(86) PCT No.: PCT/FI07/50094

§ 371 Date: Aug. 27, 2008

(30) Foreign Application Priority Data
Feb. 27, 2006 (FI) 20065140

(51) Int. Cl. B29C 45/14

(52) U.S. Cl. 264/272.15; 425/573

(57) ABSTRACT

An insert (2) is arranged in an injection mould (1) and plastic is cast onto the insert (2). The insert (2) includes at least one electronic component and connector (4) for testing the component. The injection mould (1) is provided with a counter connector (5) which is arranged to connect to the connector (4). The condition of the insert (2) is tested by a testing device connected to the counter connector (5) during the injection moulding process.

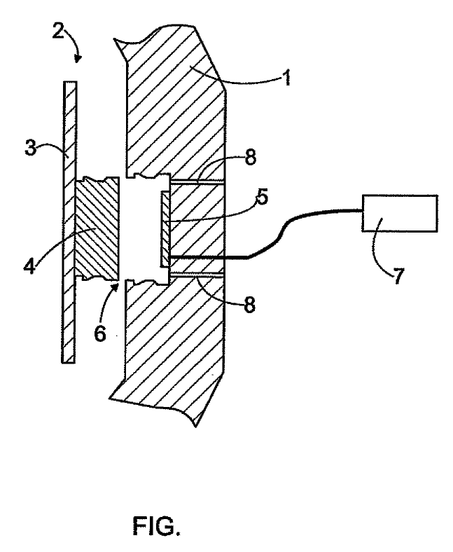

### BACKGROUND OF THE INVENTION

The invention relates to a method for forming an electronic device, the method comprising arranging an insert into an injection mould and casting plastic onto the insert.

The invention further relates to an arrangement for forming an electronic device, the arrangement comprising an injection mould and an insert arranged inside it.

One way of producing electronic devices is to arrange a switching board provided with electronic components, most commonly a circuit board, in an injection mould, in which case the switching board functions as an “insert”. Plastic is cast onto the insert, in which case the switching board forms an integrated piece with the plastic in connection with it. It is very difficult to arrange a switching board connector in a right place in the plastic structure of the object produced. Alignment of the insert with the mould requires that the insert be provided with control pins, for example, in which case the control pins engage holes in the mould. The quality of electronic devices is typically controlled by testing the devices after production and rejecting inoperative devices. The testing takes time and thus decreases the production capacity of a production line.

### BRIEF DESCRIPTION OF THE INVENTION

The object of the invention is to provide a new method and arrangement for forming an electronic device.

The method according to the invention is characterized in that the insert includes at least one electronic component and connector, the injection mould is provided with a counter connector, the insert is arranged in the injection mould so that the insert connector connects to the counter connector of the injection mould, and the condition of the insert is tested during the injection moulding process.

The arrangement according to the invention is further characterized in that the insert includes at least one electronic component and connector, the arrangement further includes a counter connector in connection with the injection mould, the insert connector being connectable to the counter connector, and a testing device connected to the counter connector for testing the condition of the insert.

In the present solution, the insert includes at least one electronic component and connector for testing the component. The insert may include a switching board, such as a circuit board, which is provided with several electronic components and a connector, or the insert is formed of a single unit consisting of a single connector and an electronic component or an electronic module or a similar structure. The insert is arranged in the injection mould and plastic is cast onto it. A counter connector is provided in the injection mould, the counter connector being arranged to connect to the connector. The condition of the insert is tested by a testing device connected to the counter connector during the injection moulding process. In that case, the testing can be performed in a quick and simple manner. This simplifies and speeds up the production process. The basic idea of an embodiment is that the condition of the insert is tested during the injection moulding process when the injection mould is closing. If an insert is found faulty, the injection moulding process may be interrupted and the faulty component rejected. In that case, the process functions very fast and no useless injection moulding element is produced, i.e. unnecessary work stages and material losses can be avoided. The basic idea of another embodiment is that the function of the insert is tested during the injection moulding process when the injection mould is opening. In that case, any failures that may have occurred during the injection moulding are detected while the testing is still fast without a separate testing phase, which requires the placement of an object to be tested for the testing. The idea of a third embodiment is that the connector functions as an alignment member of the insert, in which case the injection mould is provided with a shape corresponding to the connector shape so as to enable alignment. In that case, no separate alignment members are needed in the insert and the produced object and mould are thus relatively simple. The idea of a fourth embodiment is that the insert is sucked into the mould by low pressure, the mould being provided with low-pressure channels at the connector of the insert. In that case, the insert stays firmly fixed during injection moulding. Testing can also be performed in a very reliable manner.

### BRIEF DESCRIPTION OF THE FIGURES

The invention will now be described in greater detail in the accompanying FIGURE, which is a schematic cross-sectional side view illustrating a part of an injection mould and an insert to be arranged inside it.

For the sake of clarity, the FIGURE illustrates embodiments of the invention in a simplified manner.

### DETAILED DESCRIPTION OF EMBODIMENTS OF THE INVENTION

The FIGURE illustrates part of one half of an injection mould 1. An insert 2 is arranged inside the injection mould 1. In the accompanying FIGURE, the insert 2 is not yet in its place but is illustrated as separate from the injection mould 1 for the sake of clarity. After the insert 2 has been placed in its place, i.e. against the injection mould 1, the other half of the injection mould 1 is arranged in its place so as to form an enclosed space. Plastic is pressed into this space so as to form a casting where the insert 2 is provided in the plastic. Components related to injection moulding and the process for performing injection moulding are not described here in greater detail because these are obvious issues to a person skilled in the art.

The insert 2 is formed by a circuit board 3, which includes electronic components and a connector 4. The casting to be manufactured may be an electronic device or part of it. The electronic device may be, for example, a mobile phone, camera, portable game console, wrist computer or a similar device. Furthermore, the casting to be manufactured may be a plastic component used in the car industry into with which electronic functions, such as sensor and measuring functions, have been integrated.

The injection mould 1 includes a counter connector 5. When the insert 2 is arranged in its place against the injection mould 1, the connector 4 and the counter connector 5 connect to each other. A notch 6 whose size and shape correspond to those of the connector 4 is formed in the injection mould 1. In that case, the insert 2 can be aligned accurately with the injection mould 1 by arranging the connector 4 in the notch 6. The shape for alignment may also be implemented by providing the injection mould 1 with a protrusion and the connector 4, for example, with a corresponding recess, or in another manner.

The counter connector 5 of the injection mould 1 is connected to a testing device 7. When the connector 4 is connected to the counter connector 5, the condition of the connector's 4 circuit board 3 and its components can be tested by the testing device 7. The testing can be performed during the injection moulding process In this context, the injection moulding process is thought to start when the insert 2 is arranged inside the injection mould and to finish when the casting is removed from the injection mould 1.

The condition of the insert 2 can be tested immediately after the insert 2 has been arranged in its place, i.e. the connector 4 has been connected to the counter connector 5. The condition of the insert may thus be tested immediately at the beginning of the injection moulding process when the injection mould is closing, for example. If the insert is found faulty, the injection moulding process is interrupted and the faulty piece removed. After this, a new insert 2 is placed in the injection mould 1. This way injection moulding of a faulty piece can be avoided, i.e. it is possible to save in the material costs and speed up the manufacturing process.

The insert 2 may also be tested at the end of the injection moulding process after plastic has been cast. This allows finding out whether the insert has been damaged in the injection moulding process. Thus no separate testing after the injection moulding is necessary. The testing may be performed, for example, before casting plastic, after casting plastic, or both before and after casting plastic.

The fact that the insert 2 stays in its place in the injection mould 1 can be ensured by form-locking, for example, by providing the notch 6 and the connector 4 with corresponding form-locking members. Instead of or in addition to form-locking, the fact that the insert stays in its place can be ensured by sucking the insert 2 into its place by low pressure. In that case, the injection mould 1 is provided with low-pressure channels 8. The low-pressure channels 8 may be arranged so that the insert 2 is sucked into its place from the connector 4. In addition to the low-pressure channels 8, the FIGURE does not illustrate other arrangements necessary for generating low pressure because these are obvious to a person skilled in the art.

The object to be manufactured may be a casing of an electronic device. In that case, the insert 2 is a fixed part of the casing of the electronic device. In addition to testing, the connector 4 may be utilized as a connector of an electronic device. The connector 4 and the counter connector 5 may be conventional electronic connectors or either only optical connectors or combined electro-optical connectors. The connectors must allow insert testing through them.

It is necessary to fix the insert 2 firmly to the plastic piece onto which it is cast. The fact that the insert stays fixed may be ensured by making holes to be filled with plastic during casting in the circuit board 3.

In some cases, the features described in this application may be used as such, regardless of the other features. On the other hand, the features described in this application may be combined into various combinations.

The drawings and the related description are only intended to illustrate the inventive concept. The details of the invention may vary within the scope of the claims.

1-13. (canceled)

14. A method of forming an electronic device, the method comprising, providing an injection mould with a counter connector, arranging an insert that includes at least one electronic component and a connector in the injection mould so that the connector of the insert connects to the counter connector in the injection mould, casting plastic onto the insert and testing the condition of the insert during the injection moulding process.

15. A method according to claim 14, wherein the condition of the insert is tested at the beginning of the injection moulding process.

16. A method according to claim 14, wherein the condition of the insert is tested at the end of the injection moulding process.

17. A method according to claim 14, further comprising aligning the insert with the injection mould by means of the connector of the insert.

18. A method according to claim 14, further comprising sucking the insert into its place in the injection mould for the duration of the injection moulding process.

19. A method according to claim 14, wherein the insert includes a switching board provided with several electronic components.

20. A method according to claim 19, wherein the switching board is a circuit board.

21. An arrangement for forming an electronic device, the arrangement comprising an injection mould, an insert that includes at least one electronic component and a connector arranged inside the injection mould, a counter connector in connection with the injection mould to which the connector of the insert is connectable, and a testing device connected to the counter connector for testing the condition of the insert.

22. An arrangement according to claim 21, wherein the connector of the insert functions as an alignment member of the insert as the injection mould is provided with a shape corresponding to the shape of the connector so as to enable alignment.

23. An arrangement according to claim 21, wherein the injection mould is provided with low-pressure channels for sucking the insert into its place for the duration of the injection moulding process.

24. An arrangement according to claim 23, wherein at least one low-pressure channel is arranged at the connector of the insert.

25. An arrangement according to claim 21, wherein the insert includes a switching board provided with several electronic components.

26. An arrangement according to claim 25, wherein the switching board is a circuit board.
